(19) United States
(12) Patent Application Publication
(10) Pub. No.: US 2025/0234749 A1
(43) Pub. Date: Jul. 17, 2025

(54) DISPLAY DEVICE

(71) Applicant: Samsung Display Co., LTD., Yongin-si (KR)

(72) Inventors: EUNWON SEO, Yongin-si (KR); JOON-IK LEE, Yongin-si (KR); CHEULJIN PARK, Yongin-si (KR)

(21) Appl. No.: 18/956,054

(22) Filed: Nov. 22, 2024

(30) Foreign Application Priority Data
Jan. 16, 2024 (KR) 10-2024-0006578

(51) Int. Cl. H10K 59/80; H10K 59/121; H10K 59/38

(52) U.S. Cl. CPC H10K 59/871; H10K 59/1213; H10K 59/38; H10K 59/873; H10K 59/8794

(57) ABSTRACT

A display device includes a display panel for providing an image, a light control member disposed on the display panel, and a plate disposed under the display panel. The plate includes a first sheet, and second sheets disposed spaced apart from each other on the first sheet, and holes which are spaced apart from each other pass through each of the second sheets.

This application claims priority to Korean Patent Application No. 10-2024-0006578, filed on Jan. 16, 2024, and all the benefits accruing therefrom under 35 U.S.C. § 119, the content of which in its entirety is herein incorporated by reference.

### BACKGROUND

### 1. Field

The disclosure herein relates to a display device, and more particularly, to a display device including a plate for maintaining the flatness of a display panel.

### 2. Description of the Related Art

Multimedia electronic apparatuses such as televisions, mobile phones, tablet computers, navigation systems, game consoles, or the like, may include a display device for displaying images. A display device may include a plurality of pixels, and the pixels may each include a light-emitting element for generating light and a driving element connected to the light-emitting element.

A display device which includes an organic light-emitting element among light-emitting elements has advantages such as a wide viewing angle, a relatively fast response speed, relatively low power consumption, or the like, and therefore attracts attention as a next-generation display device. As the area of a display device becomes larger, it is desired to make a plate for maintaining the flatness of a display panel have a larger area.

### SUMMARY

The disclosure provides a lightweight and large-sized plate disposed under a large-area display panel.

An embodiment of the inventive concept provides a display device including a display panel which provides an image, a light control member disposed on the display panel, and a plate disposed under the display panel. The plate includes a first sheet, and second sheets disposed spaced apart from each other on the first sheet, and holes which are spaced apart from each other pass through each of the second sheets.

In an embodiment, the first sheet may include an invar, and the second sheets may include stainless steel.

In an embodiment, first to third holes extending in a first direction may be defined in each of the second sheets, the first hole and the second hole may be spaced apart from each other along the first direction, and the third hole may be spaced apart from each of the first hole and the second hole in an inclined direction inclined between the first direction and a second direction perpendicular to the first direction.

In an embodiment, when the first hole and the second hole, which are spaced apart from each other along the first direction, are defined as a hole group, the hole group and the second hole may each be provided in plural, and the hole groups and the second holes may be arranged alternately along the second direction.

In an embodiment, widths of the first hole and the second hole in the first direction may be greater than a width of the third hole in the first direction.

In an embodiment, each of the second sheets may extend in a first direction, and holes may be defined in each of the second sheets, the holes may be spaced apart from each other along a second direction crossing the first direction, and widths of the holes in the first direction may be same.

In an embodiment, first to fifth holes extending in a first direction may be defined in each of the second sheets, the first hole may be spaced apart from the second hole along the first direction, the fourth hole may be spaced apart from the fifth hole along the first direction with the third hole therebetween, and when the first hole and the second hole are defined as a first hole group, and the third to fifth holes are defined as a second hole group, the first hole group and the second hold group may be spaced apart along a second direction crossing the first direction.

In an embodiment, the first hole group and the second hole group may each be provided in plural, and the first hole groups and the second hole groups may be arranged alternately along the second direction.

In an embodiment, widths of the first hole and the second hole in the first direction may be greater than widths of the third to fifth holes in the first direction.

In an embodiment, the first hole, the second hole, the fourth hole, and the fifth hole may define an opened opening, and the third hole may define a closed opening.

In an embodiment, the second sheets arranged in the first direction may contact each other, the second sheets disposed in a same row may be defined as a sheet group, the sheet group may be provided in plural, and the sheet groups may be spaced apart from each other along the second direction.

In an embodiment, long holes and short holes extending in the first direction and spaced apart from each other in the first direction may be defined in each of the sheet groups, and the short holes may be spaced apart from the long holes along an inclined direction inclined between the first direction and the second direction.

In an embodiment, a first hole of one of the second sheets and a second hole of another one of the second sheets, which are adjacent to each other along the first direction, may be connected to define each of the long holes, and a fourth hole of one of the second sheets and a fifth hole of another one of the second sheets, which are adjacent to each other along the first direction, may be connected to define each of the short holes.

In an embodiment, the first sheet may have a thickness of about 25 micrometers (μm) to about 100 μm, and each of the second sheets may have a thickness of about 50 μm to about 200 μm.

In an embodiment, the first sheet may be provided in plural, the first sheets may be spaced apart from each other along a first direction and a second direction which cross each other, and each of the first sheets may have holes which are defined by passing therethrough and which are spaced apart from each other.

In an embodiment, respective portions of four of the second sheets may overlap one of the first sheets.

In an embodiment, the holes of the first sheet may have a same shape as that of the holes of the second sheet.

In an embodiment, the display device may further include a heat dissipating layer disposed between the display panel and the plate, wherein the heat dissipating layer may have graphite.

In an embodiment, the display panel may include a base substrate; a circuit element layer disposed on the base substrate and having a transistor; a display element layer having a light-emitting element connected to the transistor; and an encapsulation layer having inorganic layers covering the light-emitting element and an organic layer disposed between the inorganic layers, and the display device may further include a flexible printed circuit board disposed on one side of the display panel, and bent toward a lower part of the display panel.

In an embodiment, the light control member may include a light control layer overlapping the light-emitting element and having a quantum dot; a color filter disposed on the light control layer; a base layer disposed on the color filter; and a functional film disposed on the base layer and having at least one of a protective film, an anti-fingerprint film, or a low reflectance film.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an embodiment of a display device according to the inventive concept;

FIG. 1B is a perspective view of an embodiment of a curved display device according to the inventive concept;

FIG. 2A is an exploded perspective view of an embodiment of a display device according to the inventive concept;

FIG. 2B is a cross-sectional view of an embodiment of a partial region of a display device according to the inventive concept;

FIG. 2C is a cross-sectional view of an embodiment of a display panel according to the inventive concept;

FIG. 2D is a cross-sectional view of an embodiment of a display panel according to the inventive concept;

FIG. 3A is a plan view of an embodiment of a display panel according to the inventive concept;

FIG. 3B is an equivalent circuit diagram of an embodiment of a pixel according to the inventive concept;

FIG. 4 is an enlarged plan view of an embodiment of a display region according to the inventive concept;

FIG. 5 is a plan view of an embodiment of a plate according to the inventive concept;

FIG. 6 is a plan view of an embodiment of a plate according to the inventive concept;

FIGS. 7A to 7C are plan views of an embodiment of a plate according to the inventive concept;

FIG. 8 is a plan view of an embodiment of a plate according to the inventive concept; and

FIGS. 9A to 9C are plan views of an embodiment of a plate according to the inventive concept.

### DETAILED DESCRIPTION

In this specification, it will be understood that when an element (or region, layer, portion, etc.) is referred to as being “on”, “connected to” or “coupled to” another element or layer, it may be directly disposed on/connected to/coupled to the other element or intervening elements may be present.

Like reference numerals or symbols refer to like elements throughout the specification. In addition, in terms of drawings, the thickness and the ratio and the dimension of the element are exaggerated for effective description of the technical contents. As used herein, the term “and/or” includes any and all combinations of one or more of the associated listed items.

It will be understood that, although the terms first, second, etc. may be used herein to describe various elements, components, and/or sections, these elements, components, and/or sections should not be limited by these terms. These terms are only used to distinguish one element, component, or section from another element, component or section. For example, a first element, component, or section discussed below could be termed a second element, component, or section without departing from the teachings of the inventive concept. Singular expressions include plural expressions unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the drawing figures.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

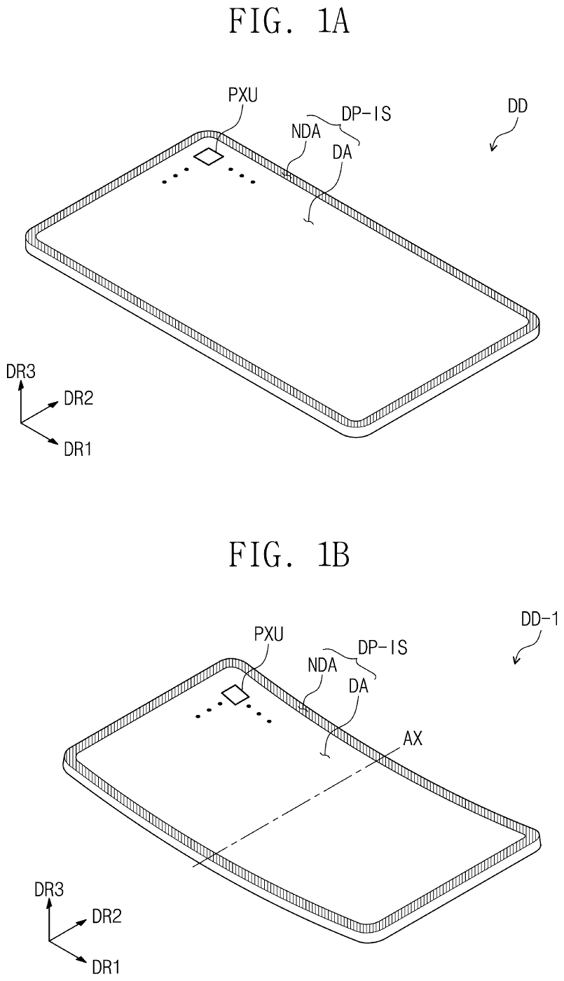

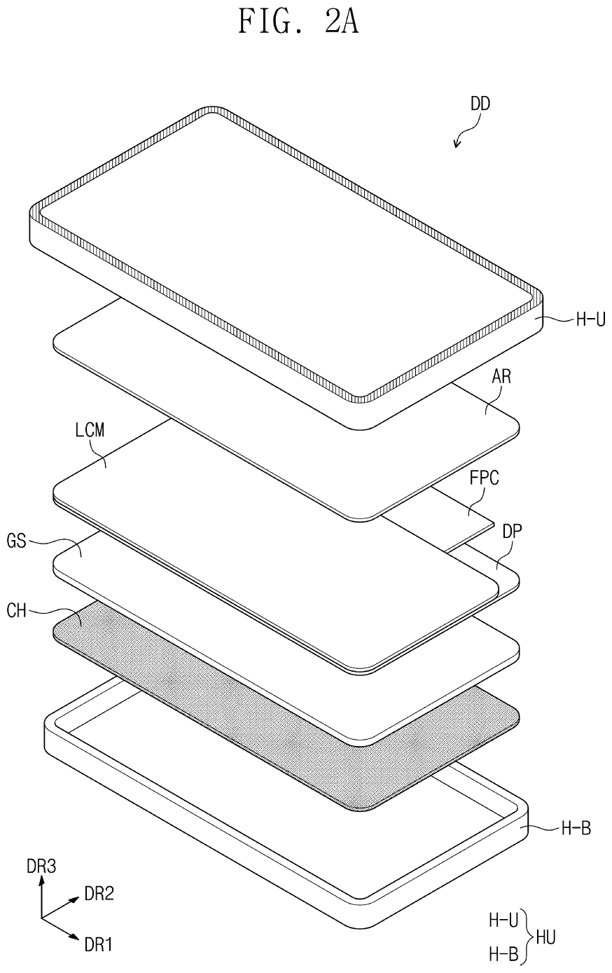

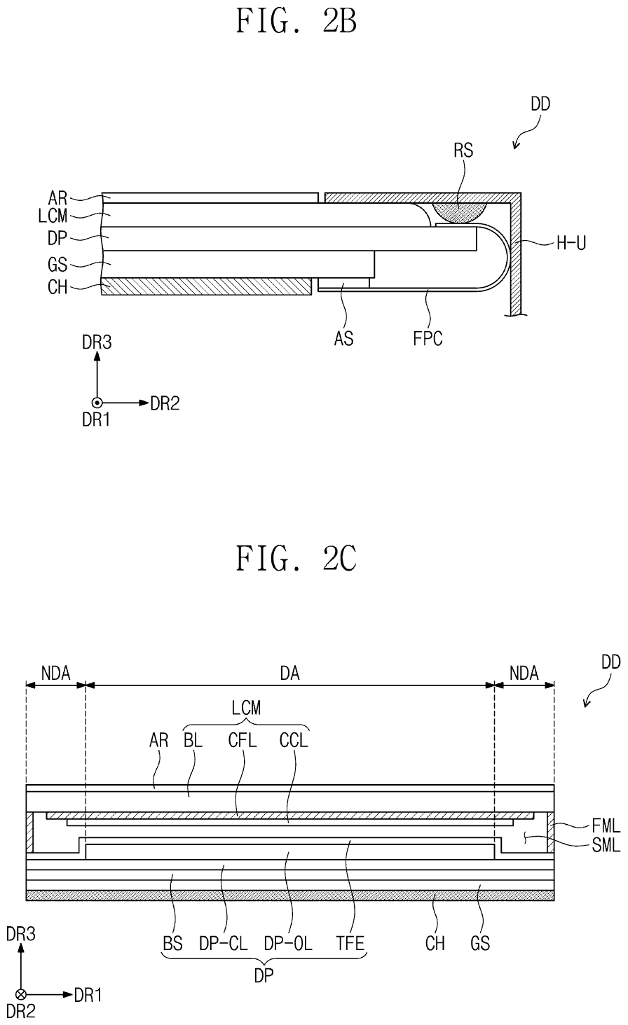

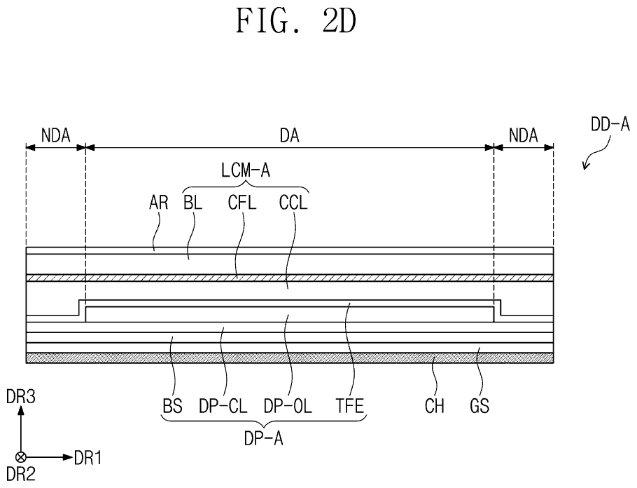

FIG. 1A is a perspective view of an embodiment of a display device according to the inventive concept. FIG. 1B is a perspective view of an embodiment of a curved display device according to the inventive concept. FIG. 2A is an exploded perspective view of a display device according to the inventive concept. FIG. 2B is a cross-sectional view of an embodiment of a partial region of a display device according to the inventive concept. FIG. 2C is a cross-sectional view of an embodiment of a display panel according to the inventive concept. FIG. 2D is a cross-sectional view of an embodiment of a display panel according to the inventive concept.

Referring to FIG. 1A, a display device DD may display an image through a display surface DP-IS. A top surface of a member disposed on an uppermost side of the display device DD may be defined as the display surface DP-IS. According to the inventive concept, a top surface of a base layer BL illustrated in FIG. 2C may be provided as the display surface DP-IS of the display device DD.

The display surface DP-IS may be parallel to a surface defined by a first direction DR1 and a second direction DR2. A normal direction of the display surface DP-IS, that is a thickness direction of the display device DD, may indicate a third direction DR3. A front surface (or top surface) and a rear surface (or bottom surface) of each of layers or units to be described below may be distinguished based on the third direction DR3.

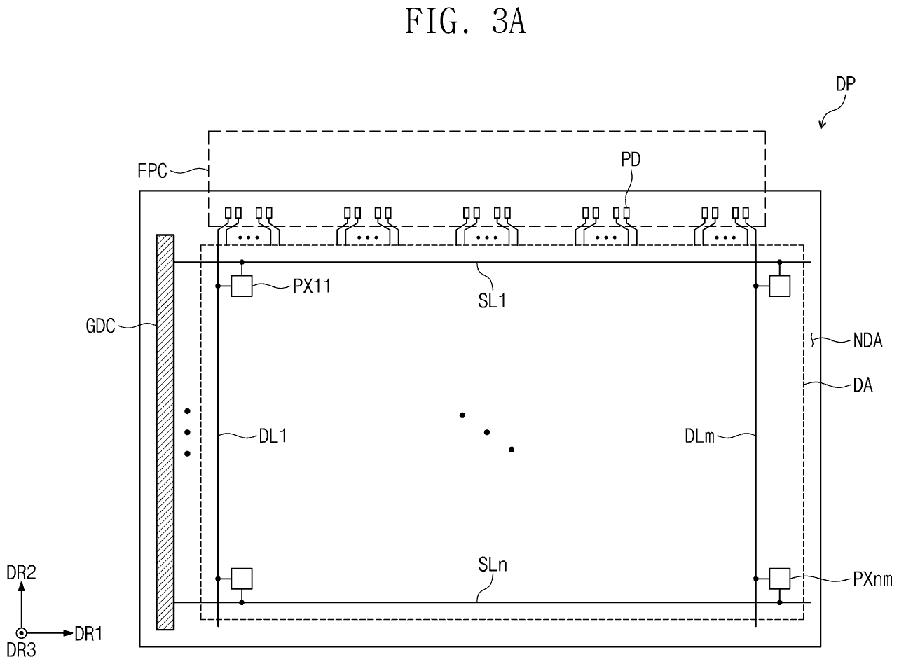

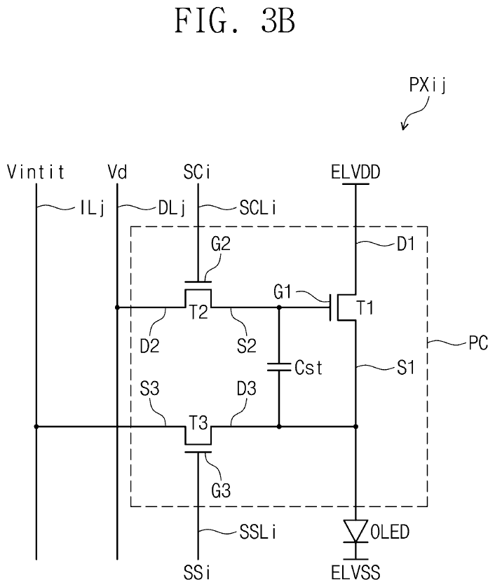

The display device DD may include a display region DA and a non-display region NDA. A light-emitting layer of a pixel PXnm (refer to FIG. 3A) may be disposed in the display region DA, and the light-emitting layer of the pixel PXnm (refer to FIG. 3A) may not be disposed in the non-display region NDA. Here, n and m may be natural numbers. The non-display region NDA may be defined along an edge of the display surface DP-IS. The non-display region NDA may surround the display region DA. In an embodiment of the inventive concept, the non-display region NDA may be omitted or may be disposed on one side of the display region DA.

Referring to FIG. 1B, a display device DD-1 in an embodiment may be a flexible display device DD-1. The display device DD-1 may be curved along the first direction DR1 with respect to an imaginary axis AX extending in the second direction DR2. However, the inventive concept is not limited thereto, and an axis may extend in the first direction DR1, or the display device may be curved with respect to a plurality of axes extending in different directions.

The display devices DD and DD-1 in an embodiment may be rollable display devices, foldable display devices or slidable display devices. Here, the display devices DD and DD-1 may have a flexible property, and may be folded or rolled by a hinge structure, or the like. Accordingly, the display devices DD and DD-1 may include a curved display surface or a three-dimensional display surface DP-IS. The three-dimensional display surface DP-IS may include a plurality of display regions which indicate different directions.

FIGS. 1A and 1B illustrate that pixel units PXU are arranged along the first direction DR1 and the second direction DR2 in the display region DA. One pixel unit PXU may be a region in which pixels for providing source light are disposed. A light-emitting area, a shape, and an arrangement form of each of the pixels included in the pixel unit PXU are not limited to any one area, shape, and arrangement form. In an embodiment, light-emitting areas of the respective pixels included in the pixel unit PXU may be different from each other, for example. In addition, light-emitting regions may each have a circular shape or a polygonal shape in a plan view.

Referring to FIGS. 2A and 2B, a display device DD in an embodiment may include a housing HU, a display panel DP, a light control member LCM, a flexible printed circuit board FPC, a functional film AR, a heat dissipating layer GS and a plate CH.

The housing HU may include an upper cover H-U and a lower cover H-B which are coupled to each other. The upper cover H-U and the lower cover H-B may be coupled to each other to define an exterior of the display device DD. The upper cover H-U and the lower cover H-B may be coupled to each other to define an internal space, and remaining components of the display device DD may be disposed in the internal space. The housing HU may include a highly rigid material. In an embodiment, the housing HU may include any one of metal or plastic, for example.

The display panel DP may display an image in response to an electrical signal. The display panel DP may include a display region DA and a non-display region NDA adjacent to the display region DA. The display region DA may be a region that is activated in response to an electrical signal. The display region DA may be a region where an image provided by the display panel DP is displayed.

The non-display region NDA may be adjacent to the display region DA. In an embodiment, the non-display region NDA may surround the display region DA, for example. However, the inventive concept is not limited thereto, and the non-display region NDA may be defined in various shapes. The non-display region NDA may be a region in which a driving circuit or driving wiring for driving the display region DA, various signal lines for providing electrical signals, and pads are disposed.

The display panel DP in an embodiment may be a light-emitting display panel, and may thus be any one of a liquid crystal display panel, an electrophoretic display panel, a microelectromechanical system display panel (“MEMS”), an electrowetting display panel, an organic light-emitting display panel, an inorganic light-emitting display panel, or a quantum-dot display panel.

In addition, the display panel DP in an embodiment of the inventive concept may include an ultra-small light-emitting element. In an embodiment, the display panel DP may include a micro light-emitting diode (“LED”) element and/or a nano LED element, for example, and is not particularly limited.

The flexible printed circuit board FPC may be coupled to the non-display region NDA of the display panel DP. The flexible printed circuit board FPC may be connected to a main circuit board.

Referring to FIG. 2B, a portion of the flexible printed circuit board FPC may be bent and disposed on a lower end of the display panel DP. In a bent state, the flexible printed circuit board FPC may be accommodated in the lower cover H-B. The portion, bent toward a lower part of the display panel DP, of the flexible printed circuit board FPC may be disposed on the heat dissipating layer GS. The bent portion of the flexible printed circuit board FPC may be attached to the heat dissipating layer GS by an adhesive layer AS. The adhesive layer AS may be omitted, and is not limited to a particular embodiment.

The display device DD in an embodiment may further include a resin RS disposed between the upper cover H-U and the flexible printed circuit board FPC. The resin RS may compensate for a step between the upper cover H-U and the display panel DP. The resin RS may absorb an impact applied from the outside, and prevent foreign matters, or the like from being introduced between the display panel DP and the light control member LCM.

The light control member LCM may be disposed on the display panel DP. The light control member LCM may include light control patterns which are capable of converting an optical property of source light provided from the display panel DP. The light control member LCM may selectively convert a wavelength or a color of the source light, or may transmit the source light. The light control member LCM may control color purity or color reproducibility of light emitted from the display panel DP, and prevent reflection of external light incident from the outside. In an embodiment, the light control member LCM may include quantum dots for converting a wavelength of the source light provided from the display panel DP.

The display device DD in an embodiment may further include the functional film AR disposed on the light control member LCM. The functional film AR may protect the light control member LCM. The functional film AR may include at least any one of a protective film, an anti-fingerprint film, or a low reflectance film.

The display device DD in an embodiment may further include the heat dissipating layer GS disposed under the display panel DP. The heat dissipating layer GS may dissipate heat generated in electronic components which are disposed therebelow. The heat dissipating layer GS may have a structure in which an adhesive layer and a graphite layer are alternately stacked.

The display device DD in an embodiment may further include the plate CH disposed under the heat dissipating layer GS. The plate CH may maintain the flatness of the flexible display panel DP. The plate CH according to the inventive concept may be provided as multiple layers having a layer for facilitating shape deformation of the plate CH, a highly rigid layer for maintaining the flatness of the display panel DP, or the like. This will be described later.

Referring to FIG. 2C, a display panel DP may include a base substrate BS, a circuit element layer DP-CL, a display element layer DP-OL, and an encapsulation layer TFE.

The base substrate BS may include a synthetic resin layer. The synthetic resin layer may include a thermosetting resin. In particular, the synthetic resin layer may include at least any one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In addition, the base substrate may include a glass substrate, a metal substrate, an organic/inorganic composite material substrate, or the like.

For the circuit element layer DP-CL, an insulating layer, a semiconductor layer, and a conductive layer are formed through a coating process, a deposition process, or the like. Then, the insulating layer, the semiconductor layer, and the conductive layer may be selectively patterned through a photolithography process and an etching process. The semiconductor layer may be included in a transistor connected to a light-emitting element OLED (refer to FIG. 3B) of a pixel. Through such a process, a semiconductor pattern, a conductive pattern, a signal line, or the like are formed. Patterns disposed in the same layer may be formed through the same process.

The circuit element layer DP-CL may include a driving circuit or a signal line constituting pixels. The display element layer DP-OLED may include the light-emitting element OLED (refer to FIG. 3B) included in each of the pixels.

The encapsulation layer TFE may be disposed on the display element layer DP-OL and may protect the light-emitting element OLED (refer to FIG. 3B). The encapsulation layer TFE may include inorganic layers and an organic layer disposed between the inorganic layers. The inorganic layers may protect the light-emitting element OLED (refer to FIG. 3B) from moisture and oxygen, and the organic layer may protect the light-emitting element OLED (refer to FIG. 3B) from foreign matters such as dust particles.

In an embodiment, the light control member LCM may be provided on the display panel DP, and then coupled to the display panel DP through a bonding process using a sealing member SML. The display panel DP may be spaced apart from the light control member LCM with the sealing member SML therebetween, and thus a predetermined space is formed.

The sealing member SML may be disposed in the non-display region NDA, which is an outer part of the display panel DP, and may prevent foreign matters, oxygen, moisture, or the like from being introduced into the display panel DP from the outside. The sealing member SML may be formed from a sealant including a curable resin.

The display device DD in an embodiment may further include a filling layer FML disposed in the space between the display panel DP and the light control member LCM. The filling layer FML may fill the space between the display panel DP and the light control member LCM. The filling layer FML may serve as a buffer between the display panel DP and the light control member LCM.

In an embodiment, the filling layer FML may perform a shock-absorbing function, or the like, and may increase the rigidity of the display device DD. The filling layer FML may be formed from a filling resin including a polymer resin. In an embodiment, the filling layer FML may be formed from a filling resin including an acrylate-based resin, an epoxy-based resin, or the like, for example. However, in an embodiment, the filling layer FML and the sealing member SML may be omitted, and the light control member LCM may be directly disposed on the display panel DP. A base layer BL may also be omitted from the light control member LCM.

The light control member LCM may include a light control layer CCL having quantum dots and a color filter CFL disposed on the light control layer CCL.

The color filter CFL may be disposed under the base layer BL. The light control layer CCL may be disposed under the color filter CFL. The base layer BL may include a light-transmitting substance. In an embodiment, the base layer BL may be a glass substrate, for example.

Referring to FIG. 2D, a display device DD-A may include a display panel DP-A and a light control member LCM-A. Unlike the display device DD illustrated in FIG. 2C, the light control member LCM-A may be directly disposed on the display panel DP-A. In this case, the sealing member SML and the filling layer FML may be omitted.

A light control layer CCL of the light control member LCM-A may be formed on an encapsulation layer TFE through a continuous process. A color filter CFL may be formed on the light control layer CCL through a continuous process. Thus, the light control layer CCL may be directly disposed on the encapsulation layer TFE, and the color filter CFL may be directly disposed on the light control layer CCL. In this specification, the wording “directly disposed” may mean that an additional adhesive layer, or the like is not provided between a component A and a component B. A base layer BL may be disposed on the color filter CFL. A functional film AR may be disposed on the base layer BL, and a heat dissipating layer GS and a plate CH may be disposed under the display panel DP-A.

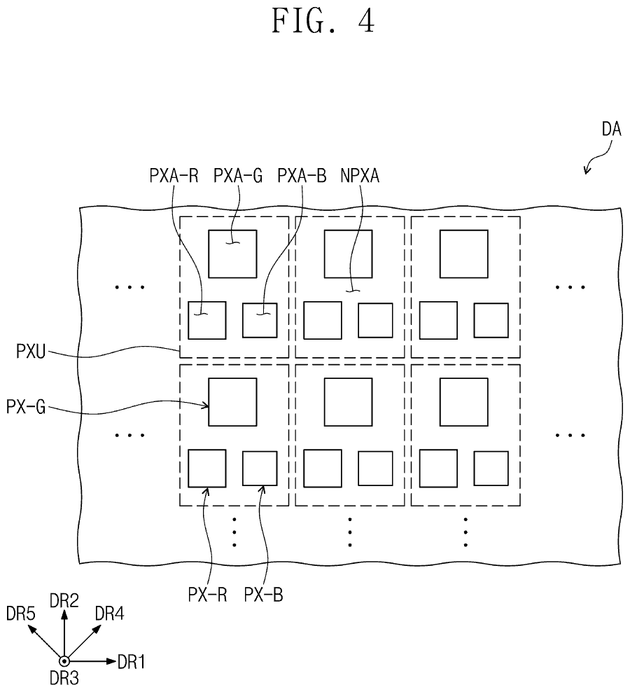

FIG. 3A is a plan view of an embodiment of a display panel according to the inventive concept. FIG. 3B is an equivalent circuit diagram of an embodiment of a pixel according to the inventive concept. FIG. 4 is an enlarged plan view of an embodiment of a display region according to the inventive concept.

FIG. 3A illustrates a planar arrangement relationship of signal lines SL1 to SLn and DL1 to DLm, and pixels PX11 to PXnm which are included in a display panel DP. The signal lines SL1 to SLn and DL1 to DLm may include a plurality of scan lines SL1 to SLn, and a plurality of data lines DL1 to DLm.

The pixels PX11 to PXnm may be disposed in a display region DA. The pixels PX11 to PXnm may each be connected to a corresponding scan line among the plurality of scan lines SL1 to SLn and a corresponding data line among the plurality of data lines DL1 to DLm. The pixels PX11 to PXnm may each include a pixel driving circuit and a light-emitting element. More types of signal lines may be provided in the display panel DP depending on a configuration of the pixel driving circuit in the pixels PX11 to PXnm.

A gate driving circuit GDC may be disposed in a non-display region NDA. The gate driving circuit GDC may be integrated into the display panel DP through an oxide silicon gate driver circuit (“OSG”) process or an amorphous silicon gate driver circuit (“ASG”) process.

The display panel DP may include display pads PD disposed in the non-display region NDA. The display pads PD may be connected to the signal lines SL1 to SLn and DL1 to DLm.

A flexible printed circuit board FPC may be coupled to the non-display region NDA of the display panel DP. The flexible printed circuit board FPC may be connected to a main circuit board. The flexible printed circuit board FPC may include substrate pads corresponding to the display pads PD, and the display pads PD and the substrate pads may be connected one to one. The display pads PD and the substrate pads may be coupled by an anisotropic conductive film. In an embodiment, a driving chip may be disposed (e.g., mounted) on the flexible printed circuit board FPC. The driving chip may correspond to a data driving circuit. However, the inventive concept is not limited thereto, and the driving chip may be disposed (e.g., mounted) on the non-display region NDA of the display panel DP.

A portion of the flexible printed circuit board FPC may be bent and disposed on a lower end of the display panel DP. In a bent state, the flexible printed circuit board FPC may be accommodated in a lower cover H-B.

FIG. 3B illustrates a circuit diagram of one pixel PXij among pixels PX11 to PXnm (i.e., i and j are natural numbers equal to or less than n and m, respectively).

The pixel PXij may include a pixel circuit PC and a light-emitting element OLED. The pixel circuit PC may include a plurality of transistors T1 to T3 and a capacitor Cst.

The plurality of transistors T1 to T3 may be formed through a low temperature polycrystalline silicon (“LTPS”) process or a low temperature polycrystalline oxide (“LTPO”) process. The first to third transistors T1 to T3 may each include any one among a silicon semiconductor and an oxide semiconductor. Here, the oxide semiconductor may include a crystalline or amorphous oxide semiconductor, and the silicon semiconductor may include an amorphous silicon or a polycrystalline silicon, but the semiconductors are not limited to a particular embodiment.

Hereinafter, the first to third transistors T1 to T3 will be described as an N-type transistor, but are not limited thereto. The first to third transistors T1 to T3 may each be a P-type transistor or an N-type transistor depending on an applied signal. Here, a source and a drain of the P-type transistor may respectively correspond to a drain and a source of the N-type transistor.

FIG. 3B illustrates the pixel PXij connected to an i-th scan line SCLi, an i-th sensing line SSLi, a j-th data line DLj, and a j-th initial line ILj.

The pixel circuit PC may include the first transistor T1 (driving transistor), the second transistor T2 (switching transistor), the third transistor T3 (sensing transistor) and the capacitor Cst. However, the pixel circuit PC may further include an additional transistor and an additional capacitor, and is not limited to a particular embodiment.

The light-emitting element OLED may be an organic light-emitting element or an inorganic light-emitting element including an anode (first electrode) and a cathode (second electrode). The anode of the light-emitting element OLED may receive a first voltage ELVDD via the first transistor T1, and the cathode of the light-emitting element OLED may receive a second voltage ELVSS. The light-emitting element OLED may receive the first voltage ELVDD and the second voltage ELVSS, and thus emit light.

The first transistor T1 may include a drain D1 that receives the first voltage ELVDD, a source S1 connected to the anode of the light-emitting element OLED, and a gate G1 connected to the capacitor Cst. The first transistor T1 may control a driving current flowing from the first voltage ELVDD to the light-emitting element OLED in response to a voltage value stored in the capacitor Cst.

The second transistor T2 my include a drain D2 connected to the j-th data line DLj, a source S2 connected to the capacitor Cst, and a gate G2 that receives an i-th first scan signal SCi. The second transistor T2 may provide a data voltage Vd to the first transistor T1 in response to the i-th first scan signal SCi.

The third transistor T3 may include a source S3 connected to the j-th initial line ILj, a drain D3 connected to the anode of the light-emitting element OLED, and a gate G3 that receives an i-th second scan signal SSi. The j-th initial line ILj may receive an initial voltage Vintit.

The capacitor Cst may store various values of voltage differences according to input signals. In an embodiment, the capacitor Cst may store a voltage corresponding to a difference between a voltage received from the second transistor T2 and the first voltage ELVDD, for example.

First to third pixels PX-G, PX-R, and PX-B illustrated in FIG. 4 may correspond to any one of the pixels PX11 to PXnm illustrated in FIG. 3A.

Referring to FIG. 4, light generated in the first pixel PX-G may be provided to a first pixel region PXA-G, light generated in the second pixel PX-R may be provided to a second pixel region PXA-R, and light generated in the third pixel PX-B may be provided to a third pixel region PXA-B. The first to third pixel regions PXA-G, PXA-R, and PXA-B may correspond to openings defined in a pixel-defining film included in a display element layer DP-OL.

A peripheral region NPXA may be disposed between the first pixel region PXA-G, the second pixel region PXA-R, and the third pixel region PXA-B. The peripheral region NPXA may define boundaries of the first to third pixel regions PXA-G, PXA-R, and PXA-B, and may prevent color mixing between the first to third pixel regions PXA-G, PXA-R, and PXA-B. In an embodiment, the peripheral region NPXA may overlap a bank included in a light control member LCM (refer to FIG. 2C) and including or consisting of a light-blocking substance.

The first to third pixels PX-G, PX-R, and PX-B may each include the light-emitting element OLED (refer to FIG. 3B), and the first to third pixels PX-G, PX-R, and PX-B may generate source light of the same color. However, the inventive concept is not limited thereto, and colors of light generated in the first to third pixels PX-G, PX-R, and PX-B may be different from each other.

The source light generated in the light-emitting elements OLED (refer to FIG. 3B) of the first to third pixels PX-G, PX-R, and PX-B may be converted into light having any one of a red color, a green color, or a blue color through the light control layer CCL included in the light control member LCM illustrated in FIG. 2C. The converted light may be emitted through the first pixel region PXA-G, the second pixel region PXA-R, and the third pixel region PXA-B.

Referring to FIG. 4, the second pixel region PXA-R and the third pixel region PXA-B may be disposed in the same row, and the first pixel region PXA-G may be disposed in a row different from a row where the second pixel region PXA-R and the third pixel region PXA-B are disposed. In an embodiment, the second pixel region PXA-R and the third pixel region PXA-B may be spaced apart from each other along a first direction DR1, and the first pixel region PXA-G may be disposed spaced apart from the second pixel region PXA-R and the third pixel region PXA-B in a diagonal (or inclined) direction (e.g., DR4 or DR5) of each of the first direction DR1 and a second direction DR2, for example.

In an embodiment, an area of the first pixel region PXA-G may be smaller than an area of the second pixel region PXA-R, and greater than an area of the third pixel region PXA-B.

In this embodiment, the first pixel region PXA-G, the second pixel region PXA-R, and the third pixel region PXA-B are illustrated as having a square shape, but a shape, an arrangement form and areas of the pixel regions are not limited thereto.

An arrangement structure of the first pixel region PXA-G, the second pixel region PXA-R, and the third pixel region PXA-B inside a pixel unit PXU illustrated in FIG. 4 is merely one of embodiments, and the inventive concept is not limited thereto. In an embodiment of the inventive concept, the first pixel region PXA-G, the second pixel region PXA-R, and the third pixel region PXA-B may be arranged along the first direction DR1 and disposed in the same row. In addition, respective arrangements of the first pixel region PXA-G, the second pixel region PXA-R, and the third pixel region PXA-B in the pixel units PXU are not necessarily same.

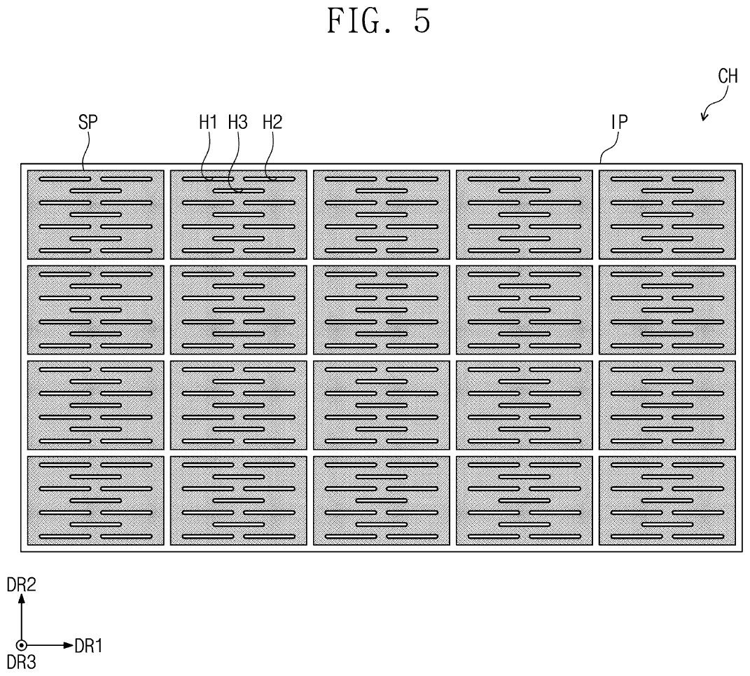

FIG. 5 is a plan view of an embodiment of a plate according to the inventive concept. A plate CH to be described with reference to FIG. 5 may be applied to the plate CH illustrated in FIGS. 2A and 2B.

The plate CH in an embodiment may include a first sheet IP and a plurality of second sheets SP disposed on the first sheet IP. The first sheet IP may be spaced apart from the heat dissipating layer GS (refer to FIG. 2A) with the second sheets SP therebetween. The plate CH may be bonded to the heat dissipating layer GS through an additional adhesive layer.

The first sheet IP may be provided in the form of a plate having a quadrangular shape along a first direction DR1 and a second direction DR2. The first sheet IP may include a more flexible substance than the second sheets SP. In an embodiment, the first sheet IP may include an invar, for example. In the plate CH in an embodiment, the second sheets SP are supported by the first sheet IP which is more flexible than the second sheets SP, and thus a shape of the plate CH may be easily deformed.

In an embodiment, the first sheet IP may have a thickness of about 25 micrometers (μm) to about 100 μm.

The second sheets SP may be spaced apart from each other along the first direction DR1 and the second direction DR2, and disposed on the first sheet IP. The second sheets SP may each be coupled to the first sheet IP through a welding process or a metal brazing process.

First to third holes H1, H2, and H3 may be defined in each of the second sheets SP. In this embodiment, the first to third holes H1, H2, and H3 may each extend along the first direction DR1.

The first hole H1 and the second hole H2 may be spaced apart from each other along the first direction DR1. The third hole H3 may be spaced apart from the first hole H1 in a first diagonal direction of the first direction DR1 and the second direction DR2, and the third hole H3 may be spaced apart from the second hole H2 in a second diagonal direction of the first direction DR1 and the second direction DR2. The first diagonal direction and the second diagonal direction may cross each other.

Widths of the first hole H1 and the second hole H2 in the first direction DR1 may be greater than a width of the third hole H3 in the first direction DR1.

When viewed in the second direction DR2, one portion of the second hole H2 may overlap the first hole H1, and another portion of the second hole H2 may overlap the third hole H3.

When first hole H1 and the second hole H2 arranged along the first direction DR1 are also referred to as a “hole group”, the hole groups and the third holes H3 may be alternately arranged along the second direction DR2.

FIG. 5 illustrates that eleven holes are defined in one second sheet SP, but the number of the holes is not limited thereto as long as the hole group and the second hole H2 are alternately arranged.

According to this embodiment, the second sheets SP may include a more rigid substance than the first sheet IP. In an embodiment, the second sheets SP may include stainless steel, for example. Since the second sheets SP include stainless steel, the plate CH may maintain the flatness of the display panel DP.

The second sheets SP may each have a thickness of about 50 μm to about 200 μm.

In this embodiment, it is illustrated that twenty second sheets SP are disposed on the first sheet IP in a 4 by 5 matrix form, but the number of the second sheets SP is not limited thereto. The number and widths of the second sheets SP may be variable depending on an area of the display panel DP (refer to FIG. 2A).

According to this embodiment, the plate CH includes the second sheets SP including or consisting of stainless steel, and thus the plate CH may maintain the flatness of the plate CH. Furthermore, since the second sheets SP are disposed spaced apart from each other on the first sheet IP and the first sheet IP that supports the second sheets SP includes an invar, a shape of the plate CH may be easily deformed. In addition, the plate CH which becomes lightweight and large-sized may be provided. Accordingly, a display device DD including a display panel DP with improved reliability may be provided.

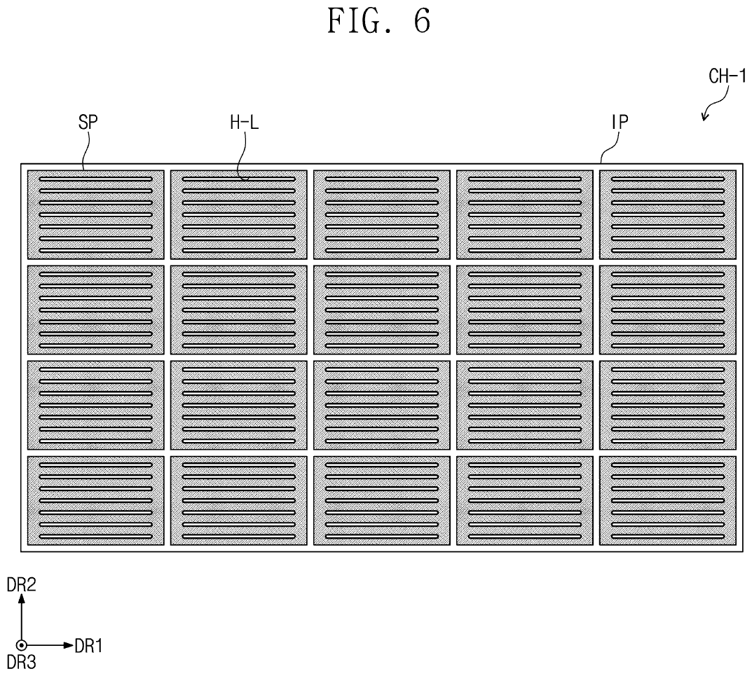

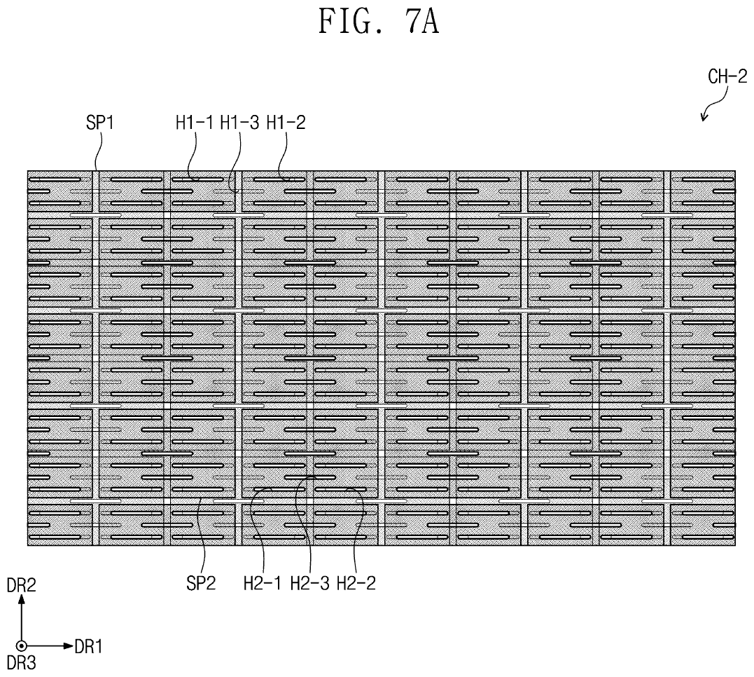

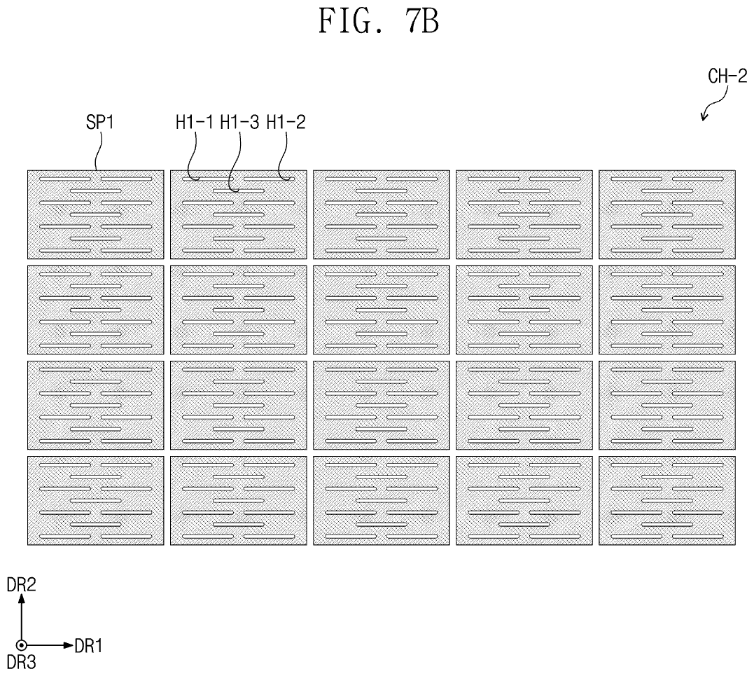

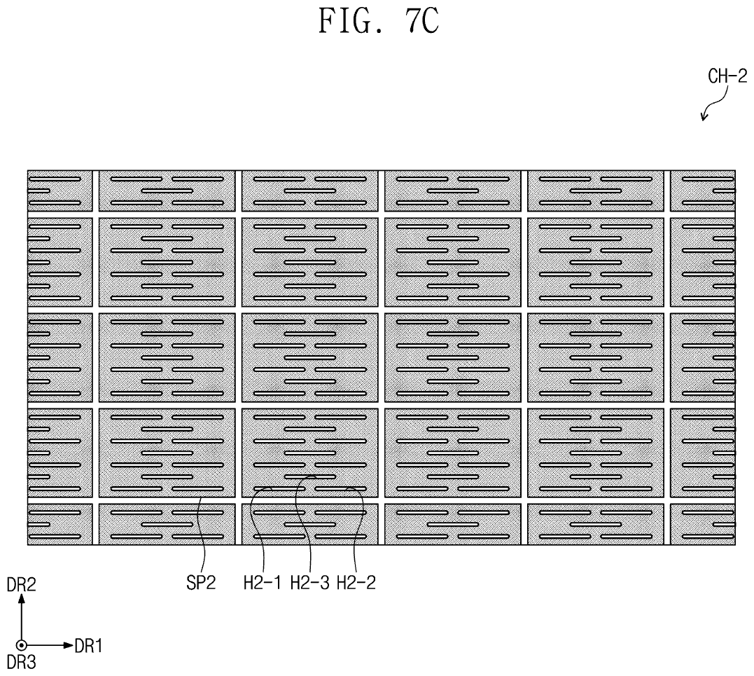

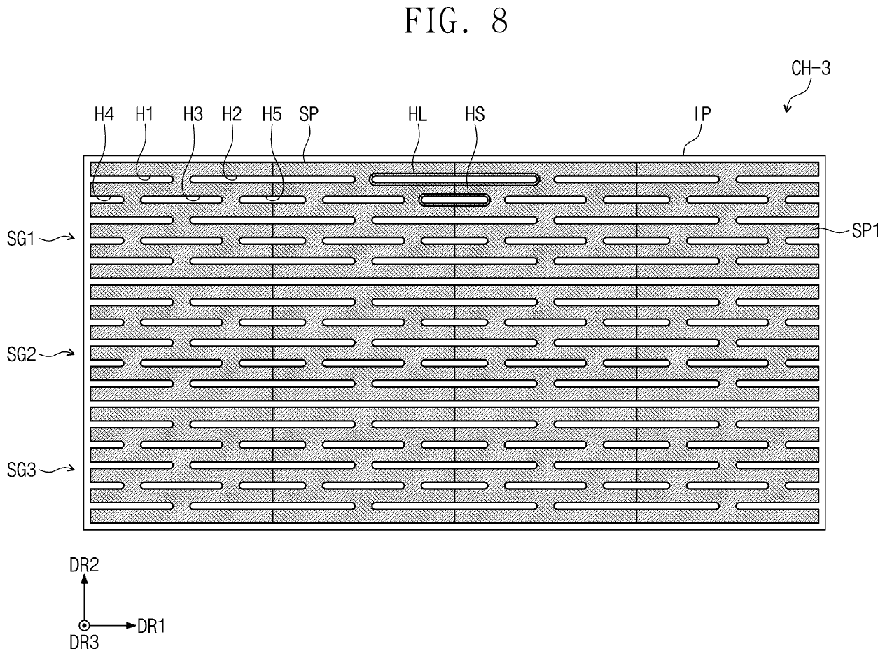

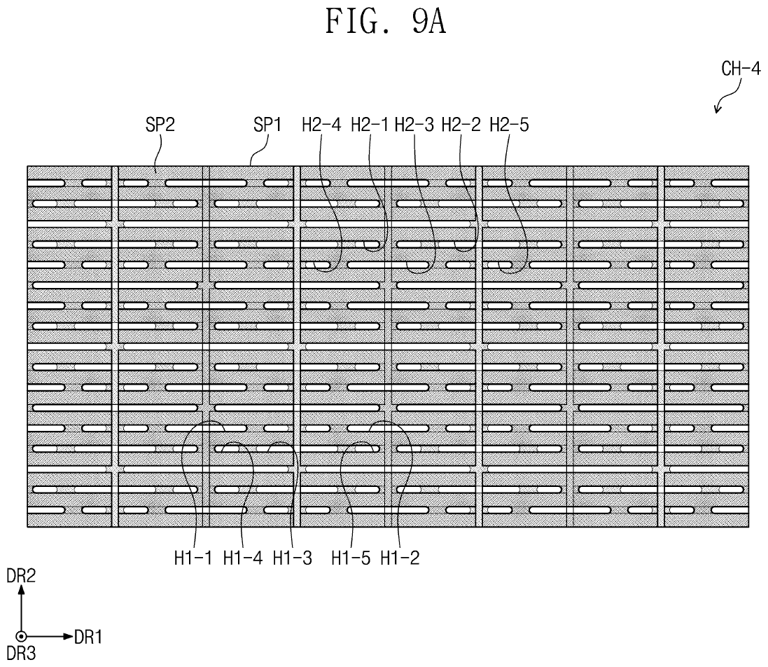

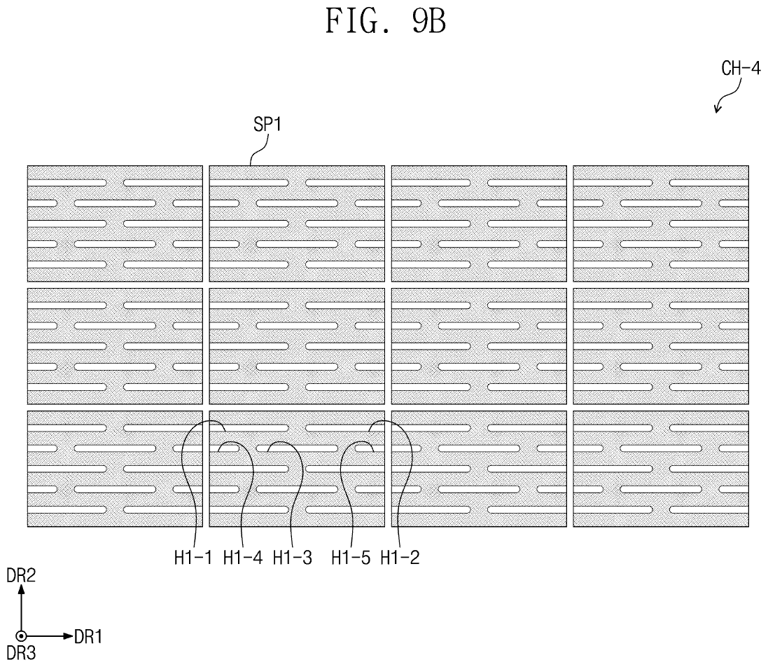

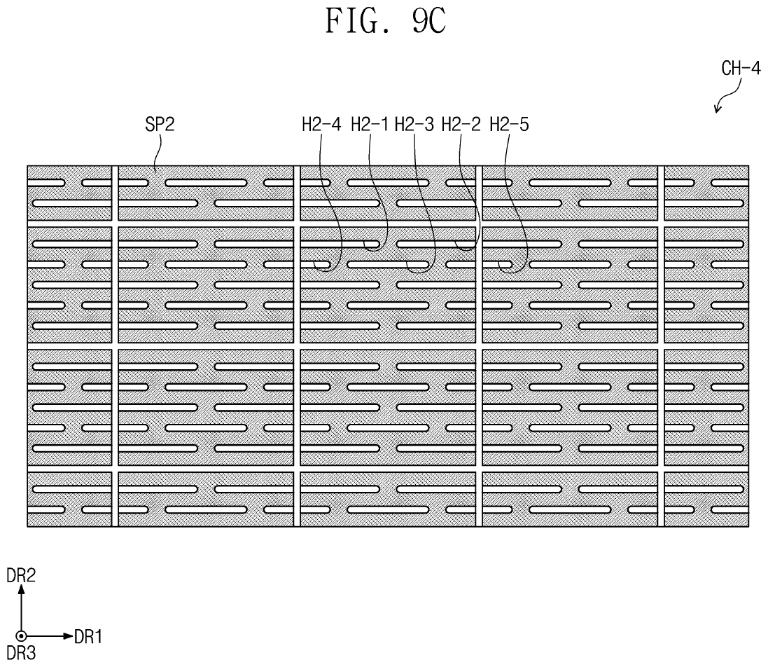

FIG. 6 is a plan view of an embodiment of a plate according to the inventive concept. FIGS. 7A to 7C are plan views of an embodiment of a plate according to the inventive concept. FIG. 8 is a plan view of an embodiment of a plate according to the inventive concept. FIGS. 9A to 9C are plan views of an embodiment of a plate according to the inventive concept. Components same as/similar to the components illustrated in FIGS. 1A to 5 will be denoted as same/similar reference numerals or symbols, and a duplicated explanation may be omitted.

Referring to FIG. 6, a plate CH-1 in an embodiment may include a first sheet IP and a plurality of second sheets SP disposed on the first sheet IP. The first sheet IP may be spaced apart from the heat dissipating layer GS (refer to FIG. 2A) with the second sheets SP therebetween. The plate CH-1 may be bonded to the heat dissipating layer GS through an additional adhesive layer.

The first sheet IP may be provided in the form of a plate having a quadrangular shape along a first direction DR1 and a second direction DR2. The first sheet IP may include an invar.

The second sheets SP may be spaced apart from each other along the first direction DR1 and the second direction DR2, and disposed on the first sheet IP. The second sheets SP may each be coupled to the first sheet IP through a welding process or a metal brazing process.

Holes H-L may be defined in the second sheets SP. In this embodiment, the holes H-L may each extend along the first direction DR1, and the holes H-L may be spaced apart from each other along the second direction DR2.

However, the inventive concept is not limited thereto, and the holes in an embodiment may each extend along the second direction DR2 and the holes may be spaced apart from each other along the first direction DR1.

Referring to FIGS. 7A to 7C, a plate CH-2 in an embodiment may include first sheets SP1 and second sheets SP2. The second sheets SP2 may be disposed on the first sheets SP1. The plate CH-2 may be bonded to the heat dissipating layer GS (refer to FIG. 2A) through an additional adhesive layer.

The first sheets SP1 may be spaced apart from each other along the first direction DR1 and the second direction DR2. In an embodiment, (1-1)-th to (1-3)-th holes H1-1, H1-2, and H1-3 may be defined in each of the first sheets SP1. In this embodiment, the (1-1)-th to (1-3)-th holes H1-1, H1-2, and H1-3 may each extend along the first direction DR1.

The (1-1)-th hole H1-1 and the (1-2)-th hole H1-2 may be spaced apart from each other along the first direction DR1. The (1-3)-th hole H1-3 may be spaced apart from the (1-1)-th hole H1-1 in a first diagonal direction of the first direction DR1 and the second direction DR2, and the (1-3)-th hole H1-3 may be spaced apart from the (1-2)-th hole H1-2 in a second diagonal direction of the first direction DR1 and the second direction DR2. The first diagonal direction and the second diagonal direction may cross each other.

When the (1-1)-th hole H1-1 and the (1-2)-th hole H1-2 arranged along the first direction DR1 are also referred to as a “first hole group”, the first hole groups and the (1-2)-th holes H1-2 may be alternately arranged along the second direction DR2. The first sheets SP1 may each include stainless steel.

The second sheets SP2 may be spaced apart from each other along the first direction DR1 and the second direction DR2. In an embodiment, (2-1)-th to (2-3)-th holes H2-1, H2-2, and H2-3 may be defined in each of the second sheets SP2. In this embodiment, the (2-1)-th to (2-3)-th holes H2-1, H2-2, and H2-3 may each extend along the first direction DR1. Respective shapes of the (2-1)-th to (2-3)-th holes H2-1, H2-2, and H2-3 in the second sheet SP2 may be the same as respective shapes of the (1-1)-th to (1-3)-th holes H1-1, H1-2, and H1-3 in the first sheet SP1.

The (2-1)-th hole H2-1 and the (2-2)-th hole H2-2 may be spaced apart from each other along the first direction DR1. The (2-3)-th hole H2-3 may be spaced apart from the (2-1)-th hole H2-1 in a first diagonal direction of the first direction DR1 and the second direction DR2, and the (2-3)-th hole H2-3 may be spaced apart from the (2-2)-th hole H2-2 in a second diagonal direction of the first direction DR1 and the second direction DR2. The first diagonal direction and the second diagonal direction may cross each other.

When the (2-1)-th hole H2-1 and the (2-2)-th hole H2-2 arranged along the first direction DR1 are also referred to as a “second hole group”, the second hole groups and the (2-2)-th holes H2-2 may be alternately arranged along the second direction DR2. The second sheets SP2 may each include stainless steel. The second sheets SP may each be coupled to the first sheets SP1 through a welding process or a metal brazing process.

According to this embodiment, four second sheets SP2 may be disposed on the first sheet SP1 such that respective portions thereof overlap the first sheet SP1. Four first sheets SP1 may be disposed on the second sheet SP2 such that respective portions thereof overlap the second sheet SP2.

In an embodiment, at least some of the holes included in the first sheets SP1 may overlap the holes included in different second sheets SP2. In addition, remaining some of the holes included in the first sheets SP1 may not overlap the holes included in the second sheets SP2.

Referring to FIG. 8, a plate CH-3 in an embodiment may include a first sheet IP and a plurality of second sheets SP disposed on the first sheet IP. The first sheet IP may be spaced apart from the heat dissipating layer GS (refer to FIG. 2A) with the second sheets SP therebetween. The plate CH-3 may be bonded to the heat dissipating layer GS through an additional adhesive layer.

The first sheet IP may be provided in the form of a plate having a quadrangular shape along a first direction DR1 and a second direction DR2. The first sheet IP may include an invar. In the plate CH-3 in an embodiment, the second sheets SP are supported by the first sheet IP which is more flexible than the second sheets SP, and thus a shape of the plate CH-3 may be easily deformed.

In an embodiment, the first sheet IP may have a thickness of about 25 μm to about 100 μm.

According to this embodiment, second sheets SP2 arranged along the first direction DR1 among the second sheets SP may contact each other. First sheets SP1 arranged along the first direction DR1 among the second sheets SP may be defined as first to third sheet groups SG1, SG2, and SG3. In each of the first to third sheet groups SG1, SG2, and SG3, three second sheets SP2 may be arranged in contact with each other along the first direction DR1. The first to third sheet groups SG1, SG2, and SG3 may be arranged spaced apart from each other along the second direction DR2. The second sheets SP may each have a thickness of about 50 μm to about 200 μm.

First to fifth holes H1, H2, H3, H4, and H5 may be defined in the second sheets SP2. The first hole H1 and the second hole H2 may each extend along the first direction DR1, and the first hole H1 and the second hole H2 may be spaced apart from each other along the first direction DR1.

The third to fifth holes H3, H4, and H5 may each extend along the first direction DR1, and the third to fifth holes H3, H4, and H5 may be spaced apart from one another along the first direction DR1.

Widths of the first hole H1 and the second hole H2 in the first direction DR1 may be greater than widths of the third to fifth holes H3, H4, and H5 in the first direction DR1. When the first hole H1 and the second hole H2 are defined as a first hole group, and the third to fifth holes H3, H4, and H5 are defined as a second hole group, the first hole groups and the second hole groups may be alternately arranged along the second direction DR2. The second hole group may be shifted by a predetermined distance along the first direction DR1 with respect to the first hole group.

According to this embodiment, portions of the first hole H1 and the second hole H2 may each define an opened opening. In addition, portions of the fourth hole H4 and the fifth hole H5 may each define an opened opening. The third hole H3 may define a closed opening.

The second sheets SP2 may each be coupled to the first sheet IP through a welding process or a metal brazing process.

A long hole HL and a short hole HS may be defined in the first to third sheet groups SG1, SG2, and SG3. The long hole HL may be defined by connecting the first hole H1 and the second hole H2, which are included in the two different second sheets SP2 adjacent to each other along the first direction DR1, to each other. In an embodiment, the second hole H2 included in one second sheet SP2 and the first hole H1 included in another sheet, which is spaced apart from the one second sheet SP2 along the first direction DR1, may be connected to each other, thereby forming one long hole HL, for example.

The short hole HS may be defined by connecting the fourth hole H4 and the fifth hole H5, which are included in the two different second sheets SP2 adjacent to each other along the first direction DR1, to each other. In an embodiment, the fifth hole H5 included in one second sheet SP2 and the fourth hole H4 included in another sheet, which is spaced apart from the one second sheet SP2 along the first direction DR1, may be connected to each other, thereby forming one short hole HS, for example.

According to this embodiment, since the second sheets SP2 arranged along the first direction DR1 contact each other, a hole continuity may be maintained. Accordingly, although a shape of the plate CH-3 is deformed, stress applied to the second sheets SP2 may be reduced.

Referring to FIGS. 9A to 9C, a plate CH-4 in an embodiment may include first sheets SP1 and second sheets SP2. The second sheets SP2 may be disposed on the first sheets SP1. The plate CH-4 may be bonded to the heat dissipating layer GS (refer to FIG. 2A) through an additional adhesive layer.

The first sheets SP1 may be spaced apart from each other along a first direction DR1 and a second direction DR2. In an embodiment, (1-1)-th to (1-5)-th holes H1-1, H1-2, H1-3, H1-4, and H1-5 may be defined in each of the first sheets SP1. In this embodiment, the (1-1)-th to (1-5)-th holes H1-1, H1-2, H1-3, H1-4, and H1-5 may each extend along the first direction DR1.

The (1-1)-th hole H1-1 and the (1-2)-th hole H1-2 may each extend along the first direction DR1, and the (1-1)-th hole H1-1 and the (1-2)-th hole H1-2 may be spaced apart from each other along the first direction DR1.

Widths of the (1-1)-th hole H1-1 and the (1-2)-th hole H1-2 in the first direction DR1 may be greater than widths of the (1-3)-th to (1-5)-th holes H1-3, H1-4, and H1-5 in the first direction DR1. When the (1-1)-th hole H1-1 and the (1-2)-th hole H1-2 are defined as a first hole group, and the (1-3)-th to (1-5)-th holes H1-3, H1-4, and H1-5 are defined as a second hole group, the first hole groups and the second hole groups may be alternately arranged along the second direction DR2. The second hole group may be shifted by a predetermined distance along the first direction DR1 with respect to the first hole group.

According to this embodiment, portions of the (1-1)-th hole H1-1 and the (1-2)-th hole H1-2 may each define an opened opening. In addition, portions of the (1-4)-th hole H1-4 and the (1-5)-th hole H1-5 may each define an opened opening. The (1-3)-th hole H1-3 may define a closed opening.

The second sheets SP2 may each be coupled to the first sheet IP through a welding process or a metal brazing process.

The second sheets SP2 may be spaced apart from each other along the first direction DR1 and the second direction DR2. In an embodiment, (2-1)-th to (2-5)-th holes H2-1, H2-2, H2-3, H2-4, and H2-5 may be defined in each of the second sheets SP2. In this embodiment, the (2-1)-th to (2-5)-th holes H2-1, H2-2, H2-3, H2-4, and H2-5 may each extend along the first direction DR1.

The (2-1)-th hole H2-1 and the (2-2)-th hole H2-2 may each extend along the first direction DR1, and the (2-1)-th hole H2-1 and the (2-2)-th hole H2-2 may be spaced apart from each other along the first direction DR1.

Widths of the (2-1)-th hole H2-1 and the (2-2)-th hole H2-2 in the first direction DR1 may be greater than widths of the (2-3)-th to (2-5)-th holes H2-3, H2-4, and H2-5 in the first direction DR1. When the (2-1)-th hole H2-1 and the (2-2)-th hole H2-2 are defined as a third hole group, and the (2-3)-th to (2-5)-th holes H2-3, H2-4, and H2-5 are defined as a fourth hole group, the third hole groups and the fourth hole groups may be alternately arranged along the second direction DR2. The fourth hole group may be shifted by a predetermined distance along the first direction DR1 with respect to the third hole group.

According to this embodiment, portions of the (2-1)-th hole H2-1 and the (2-2)-th hole H2-2 may each define an opened opening. In addition, portions of the (2-4)-th hole H2-4 and the (2-5)-th hole H2-5 may each define an opened opening. The (2-3)-th hole H2-3 may define a closed opening.

In this embodiment, respective shapes of the (2-1)-th to (2-5)-th holes H2-1, H2-2, H2-3, H2-4, and H2-5 in the second sheet SP2 may be the same as respective shapes of the (1-1)-th to (1-5)-th holes H1-1, H1-2, H1-3, H1-4, and H1-5 in the first sheet SP1.

According to this embodiment, four second sheets SP2 may be disposed on the first sheet SP1 such that respective portions thereof overlap the first sheet SP1. Four respective first sheets SP1 may be disposed on the second sheet SP2 such that respective portions thereof overlap the second sheet SP2.

In an embodiment, at least some of the holes included in the first sheets SP1 may overlap the holes included in different second sheets SP2. In addition, remaining some of the holes included in the first sheets SP1 may not overlap the holes included in the second sheets SP2.

In an embodiment of the inventive concept, since a plate disposed under a display panel is provided as multiple layers having an easily deformable sheet and highly rigid sheets, protection of the display panel may be easy, and flatness of the display panel may be improved.

In the above, description has been made with reference to embodiments, but those skilled in the art or those of ordinary skill in the relevant technical field may understand that various modifications and changes may be made to the inventive concept within the scope not departing from the spirit and the technology scope of the inventive concept described in the claims to be described later.

Therefore, embodiments disclosed in the inventive concept are not intended to limit the technical spirit of the inventive concept, and all technical ideas within the scope of the following claims and their equivalents should be construed as being included in the scope of the inventive concept.

What is claimed is:

1. A display device comprising:
a display panel which provides an image;
a light control member disposed on the display panel; and
a plate disposed under the display panel, the plate including:
a first sheet, and
second sheets disposed spaced apart from each other on the first sheet,
wherein holes which are spaced apart from each other pass through each of the second sheets.

2. The display device of claim 1, wherein the first sheet comprises an invar, and the second sheets comprise stainless steel.

3. The display device of claim 1, wherein first to third holes extending in a first direction are defined in each of the second sheets,
the first hole and the second hole are spaced apart from each other along the first direction, and
the third hole is spaced apart from each of the first hole and the second hole in an inclined direction inclined between the first direction and a second direction perpendicular to the first direction.

4. The display device of claim 3, wherein when the first hole and the second hole, which are spaced apart from each other along the first direction, are defined as a hole group, the hole group and the third hole are each provided in plural, and
hole groups and third holes are arranged alternately along the second direction.

5. The display device of claim 3, wherein each of a width of the first hole and the second hole in the first direction are greater than a width of the third hole in the first direction.

6. The display device of claim 1, wherein each of the second sheets extends in a first direction,
holes are defined in each of the second sheets,
the holes are spaced apart from each other along a second direction crossing the first direction, and
widths of the holes in the first direction are same.

7. The display device of claim 1, wherein first to fifth holes extending in a first direction are defined in each of the second sheets,
the first hole is spaced apart from the second hole along the first direction,
the fourth hole is spaced apart from the fifth hole along the first direction with the third hole therebetween, and
when the first hole and the second hole are defined as a first hole group, and the third to fifth holes are defined as a second hole group, the first hole group and the second hold group are spaced apart along a second direction crossing the first direction.

8. The display device of claim 7, wherein the first hole group and the second hole group are each provided in plural, and
first hole groups and second hole groups are arranged alternately along the second direction.

9. The display device of claim 7, wherein each of a width of the first hole and the second hole in the first direction is greater than each of a width of the third to fifth holes in the first direction.

10. The display device of claim 7, wherein the first hole, the second hole, the fourth hole, and the fifth hole define an opened opening, and
the third hole defines a closed opening.

11. The display device of claim 8, wherein the second sheets arranged in the first direction contact each other,
the second sheets disposed in a same row are defined as a sheet group,
the sheet group is provided in plural, and
sheet groups are spaced apart from each other along the second direction.

12. The display device of claim 11, wherein the sheet groups each comprise long holes and short holes extending in the first direction and spaced apart from each other in the first direction, and
the short holes are spaced apart from the long holes along an inclined direction inclined between the first direction and the second direction.

13. The display device of claim 12, wherein a first hole of one of the second sheets and a second hole of another one of the second sheets, which are adjacent to each other along the first direction, are connected to define each of the long holes, and
a fourth hole of one of the second sheets and a fifth hole of another one of the second sheets, which are adjacent to each other along the first direction, are connected to define each of the short holes.

14. The display device of claim 1, wherein the first sheet has a thickness of about 25 micrometers to about 100 micrometers, and
each of the second sheets has a thickness of about 50 micrometers to about 200 micrometers.

15. The display device of claim 1, wherein the first sheet is provided in plural,
first sheets are spaced apart from each other along a first direction and a second direction which cross each other, and
each of the first sheets has holes which are defined by passing therethrough and which are spaced apart from each other.

16. The display device of claim 15, wherein respective portions of four of the second sheets overlap one of the first sheets.

17. The display device of claim 16, wherein the holes of the first sheet have a same shape as a shape of the holes of the second sheet.

18. The display device of claim 1, further comprising a heat dissipating layer disposed between the display panel and the plate,
wherein the heat dissipating layer includes graphite.

19. The display device of claim 1, wherein the display panel comprises:
a base substrate;
a circuit element layer disposed on the base substrate and including a transistor;
a display element layer including a light-emitting element connected to the transistor; and
an encapsulation layer including inorganic layers covering the light-emitting element and an organic layer disposed between the inorganic layers, and
the display device further comprising a flexible printed circuit board disposed on one side of the display panel, and bent toward a lower part of the display panel.

20. The display device of claim 19, wherein the light control member comprises:
a light control layer overlapping the light-emitting element and including a quantum dot;
a color filter disposed on the light control layer;
a base layer disposed on the color filter; and
a functional film disposed on the base layer and including at least one of a protective film, an anti-fingerprint film, or a low reflectance film.
